(19) United States
(12) Patent Application Publication
(10) Pub. No.: US 2006/0092067 A1
(43) Pub. Date: May 4, 2006

(54) FRONT END CIRCUIT OF VOLTAGE REGULATOR

(76) Inventor: Don Liu, Hsinchu City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/904,216

(22) Filed: Oct. 29, 2004

(51) Int. Cl. H03M 1/12

(52) U.S. Cl. 341/155

(57) ABSTRACT

A front end circuit of a voltage regulator is provided. The front end circuit comprises an analog front end, a low-resolution analog-to-digital converter, and a reference voltage provider. The front end circuit emulates the performance of a high-resolution analog-to-digital converter by coupling the analog front end to the low-resolution analog-to-digital converter. The reference voltage provider provides two closely interrelated reference voltages which track each other. The digital design can remove narrow pulses easily. Therefore the front end circuit has a higher noise resistance, and costs much lower than the high-resolution analog-to-digital converter of the prior art.

### BACKGROUND OF THE INVENTION

1. Field of the Invention

The present invention relates to a front end circuit of a voltage regulator. More particularly, the present invention relates to a front end circuit of a voltage regulator which utilizes closely interrelated reference voltages.

2. Description of the Related Art

In voltage regulators there is a controlling circuit in charge of providing a regulated and noise-free pulse voltage output based on an operating voltage from an unregulated voltage source. The challenge is making a controlling circuit with high noise resistance and low cost.

FIG. 1 shows a prior art controlling circuit. It comprises an amplifier 101, a waveform generator 102, and a comparator 103. The amplifier 101 amplifies an unregulated operating voltage 104. The waveform generator 102 outputs a sawtooth waveform generated by charging and discharging. The comparator 103 compares the output waveforms of the amplifier 101 and the waveform generator 102, and then outputs a pulse voltage 105, which is regulated and noise-free. The problem of this circuit is that it cannot handle noises very well due to its analog design.

FIG. 2 shows another prior art controlling circuit. It comprises an analog-to-digital converter (ADC) 201, which receives the operating voltage 104 and outputs the pulse voltage 105. The pulse voltage 105 is regulated by the intrinsic transfer characteristics of the ADC 201. This circuit has a high resistance against noises, but it requires an ADC with a high resolution, for example, 10 bits or more. High-resolution ADCs are expensive. Therefore the cost of this circuit is much higher than that of the circuit in FIG. 1. If the circuit in FIG. 2 is adopted, the final product will be less competitive because the total cost will increase dramatically.

So far there is no controlling circuit which is able to filter out noises effectively at a low cost. Therefore we need a better solution to solve the problems of the prior art.

### SUMMARY OF THE INVENTION

Accordingly, the present invention is directed to a front end circuit of a voltage regulator, which serves as the front end of the controlling circuit of a voltage regulator. The purpose of the front end circuit is solving the problems of the prior art by achieving high noise resistance at a low cost.

According to an embodiment of the present invention, a front end circuit of a voltage regulator is provided. The front end circuit comprises an analog front end, an analog-to-digital converter, and a reference voltage provider.

The analog front end is configured to receive an operating voltage and a first reference voltage. It provides an amplified voltage which is produced according to the equation Va=(Vo−V1)*n+V1, wherein Va is the amplified voltage, Vo is the operating voltage, V1 is the first reference voltage, and n is a number greater than or equal to one.

The analog-to-digital converter is coupled to the analog front end. It is configured to receive the amplified voltage and a second reference voltage, and to provide a digitalized voltage which is produced by digitalizing the amplified voltage and using the second reference voltage as the reference during the digitalization process.

The reference voltage provider is coupled to the analog front end and the analog-to-digital converter. It is configured to provide the first reference voltage and the second reference voltage. Moreover, the first reference voltage tracks the second reference voltage according to the equation V1=k*V2, wherein V1 is the first reference voltage, V2 is the second reference voltage, and k is a positive number.

According to another embodiment of the present invention, a front end circuit of a voltage regulator is provided. The front end circuit comprises an analog front end, an analog-to-digital converter, and a reference voltage provider.

The analog front end is configured to receive an operating voltage and a first reference voltage. It provides an amplified voltage which is produced according to the equation Va=(Vo−V1)*n+V1, wherein Va is the amplified voltage, Vo is the operating voltage, V1 is the first reference voltage, and n is a number greater than or equal to one.

The analog-to-digital converter is coupled to the analog front end. It is configured to receive the amplified voltage and a second reference voltage, and to provide a digitalized voltage which is produced by digitalizing the amplified voltage and using the second reference voltage as the reference during the digitalization process.

The reference voltage provider is coupled to the analog front end and the analog-to-digital converter. It is configured to provide the first reference voltage and the second reference voltage. Moreover, the first reference voltage is equal to the second reference voltage.

The present invention emulates the performance of an analog-to-digital converter with a higher resolution by coupling an analog front end to an analog-to-digital converter with a lower resolution. The digital design allows the controlling circuit to remove narrow pulses easily. Therefore the present invention has a higher noise resistance, and costs much lower than the high-resolution analog-to-digital converter of the prior art.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a circuit diagram showing a prior art controlling circuit of a voltage regulator.

FIG. 2 is a circuit diagram showing another prior art controlling circuit of a voltage regulator.

FIG. 3 is a circuit diagram showing a controlling circuit of a voltage regulator, which includes a preferred embodiment of the front end circuit of the present invention.

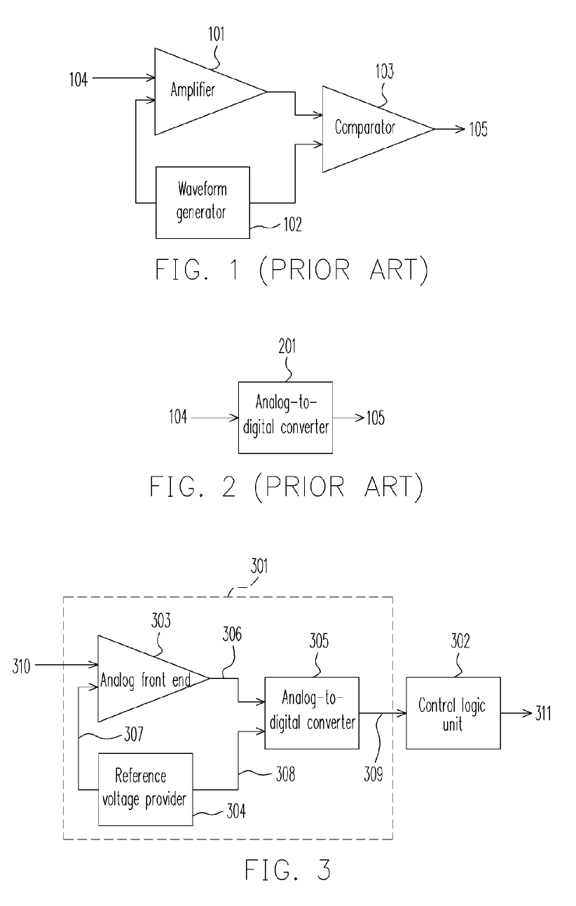

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

FIG. 3 shows a controlling circuit of a voltage regulator. The controlling circuit comprises a control logic unit 302 and a front end circuit 301, which is a preferred embodiment of the present invention. The front end circuit 301 provides a digitalized voltage 309 based on an operating voltage 310 from an unregulated voltage source (not shown). The control logic unit 302 receives the digitalized voltage 309 and provides a pulse voltage 311 produced by removing noises from the digitalized voltage 309.

The front end circuit 301 comprises an analog front end 303, an analog-to-digital converter (ADC) 305, and a reference voltage provider 304. Each one of the three components mentioned above is coupled to the other two.

The analog front end 303 is configured to receive the operating voltage 310 and the reference voltage 307. It provides the amplified voltage 306 which is produced according to the equation Va=(Vo−V1)*n+V1. Va is the amplified voltage 306, Vo is the operating voltage 310, V1 is the reference voltage 307, and n is a number greater than or equal to one. In this embodiment, the number n is about 75. The value of n can be adjusted according to actual need.

The ADC 305 is configured to receive the amplified voltage 306 and another reference voltage 308. It provides the digitalized voltage 309, which is produced by digitalizing the amplified voltage 306. The reference voltage 308 is used as the reference during the digitalization process.

The reference voltage provider 304 is configured to provide the reference voltages 307 and 308. These two reference voltages track each other according to the equation V1=k*V2, wherein V1 is the reference voltage 307, V2 is the reference voltage 308, and k is a positive number. Whenever one of the reference voltages 307 and 308 drifts due to temperature or fabrication process, the other one will respond to maintain the proportion relationship. The value of the number k can be one, so the reference voltages 307 and 308 are virtually identical.

In brief, The analog front end 303 amplifies the operating voltage 310 and outputs the result as the amplified voltage 306 to the ADC 305. The ADC 305 digitalizes the amplified voltage 306 and outputs the result as the digitalized voltage 309 to the control logic unit 302. The reference voltage provider 304 provides the reference voltages 307 and 308, which are closely interrelated to ensure that the analog front end 303 and the ADC 305 can work correctly.

In this embodiment, the resolution of the ADC 305 is 6 bits. With the help of the analog front end 303, the ADC 305 can emulate the performance of a 13-bit ADC. The amplification factor (about 75) of the analog front end 303 is enough to compensate the resolution difference of 7 bits. Furthermore, the digital design allows the control logic unit 302 to remove narrow pulses easily. Therefore the present invention has a high noise resistance, and costs much lower than the high-resolution analog-to-digital converter of the prior art.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. A front end circuit of a voltage regulator, comprising:
an operating amplifier configured to receive an operating voltage and a first reference voltage, and to provide an amplified voltage which is produced by an amplification based on said operating voltage and said first reference voltage;
an analog-to-digital converter coupled to said operating amplifier and is configured to receive said amplified voltage and a second reference voltage, and to provide a digitalized voltage which is produced by digitalizing said amplified voltage and using said second reference voltage as the reference during the digitalization process; and
a reference voltage provider coupled to said operating amplifier and said analog-to-digital converter and is configured to provide said first reference voltage and said second reference voltage, wherein said first reference voltage tracks said second reference voltage according to the equation V1=k*V2, wherein V1 is said first reference voltage, V2 is said second reference voltage, and k is positive number.

2. The front end circuit according to claim 1, wherein said amplified voltage is produced according to the equation Va=(Vo−V1)*n+V1, wherein Va is said amplified voltage, Vo is said operating voltage, V1 is said first reference voltage, and n is a predetermined number greater than or equal to one.

3. The front end circuit according to claim 2, wherein the number n is about 75.

4. The front end circuit according to claim 1, wherein said analog-to-digital converter has a resolution of 6 bits.

5. The front end circuit according to claim 1, wherein said digitalized voltage is feed into a control logic unit, which is configured to provide a pulse voltage produced by removing noises from said digitalized voltage.

6. A front end circuit of a voltage regulator, comprising:
an operating amplifier configured to receive an operating voltage and a first reference voltage, and to provide an amplified voltage which is produced by an amplification based on said operating voltage and said first reference voltage;
an analog-to-digital converter, able to emulate the performance of 13 bits analog-to-digital converter at 6 bits of resolution, coupled to said operating amplifier and is configured to receive said amplified voltage and a second reference voltage, and to provide a digitalized voltage which is produced by digitalizing said amplified voltage and using said second reference voltage as the reference during the digitalization process; and
a reference voltage provider coupled to said operating amplifier and said analog-to-digital converter and is configured to provide said first reference voltage and said second reference voltage, wherein said first reference voltage is equal to said second reference voltage.

7. A front end circuit of a voltage regulator, comprising:
an operating amplifier configured to receive an operating voltage and a first reference voltage, and to provide an amplified voltage which is produced by an amplification based on said operating voltage and said first reference voltage;
an analog-to-digital converter, coupled to said operating amplifier and is configured to receive said amplified voltage and a second reference voltage, and to provide a digitalized voltage which is produced by digitalizing said amplified voltage and using said second reference voltage as the reference during the digitalization process; and
a reference voltage provider coupled to said operating amplifier and said analog-to-digital converter and is configured to provide said first reference voltage and said second reference voltage, wherein said first reference voltage is equal to said second reference voltage, wherein said amplified voltage is produced according to the equation Va=(Vo−V1)*n+V1, wherein Va is said amplified voltage, Vo is said operating voltage, V1 is said first reference voltage, and n is a predetermined number greater than or equal to one.

8. The front end circuit according to claim 7, wherein the number n is about 75.

9. The front end circuit according to claim 6, wherein said analog-to-digital converter has a resolution of 6 bits.

10. The front end circuit according to claim 6, wherein said digitalized voltage is feed into a control logic unit, which is configured to provide a pulse voltage produced by removing noises from said digitalized voltage.
